(19) United States
(12) Patent Application Publication
(10) Pub. No.: US 2025/0233062 A1
(43) Pub. Date: Jul. 17, 2025

(54) Interposer

(71) Applicant: TE Connecitivity Japan G. K., Kawasaki-shi (JP)

(72) Inventors: Shinichi Hashimoto, Kawasaki-shi (JP); Hiroshi Shirai, Kawasaki-shi (JP); Hirotate Kadobayashi, Kawasaki-shi (JP)

(73) Assignee: TE Connecitivity Japan G. K., Kawasaki-shi (JP)

(21) Appl. No.: 19/029,351

(22) Filed: Jan. 17, 2025

(30) Foreign Application Priority Data
Jan. 17, 2024 (JP) 2024-005540

(51) Int. Cl. H01L 23/498

(52) U.S. Cl. CPC H01L 23/49827; H01L 23/49838

(57) ABSTRACT

An interposer comprises a housing and a signal contact pair. The housing has a first face and a second face, and a plurality of through holes extending therebetween. Each signal contact has a base portion press-fitted into a respective one of the through holes, a first signal contact beam extending outward from the first face from the base portion and having a first contact portion, and a second signal contact beam extending outward from the second face from the base portion and having a second contact portion. The signal contact has an opening defined by the base portion and the first signal contact beam and an opening defined by the base portion and the second signal contact beam. At least one of the two signal contacts includes protruding portions protruding toward a side of the opening, respectively, from the base portion and at least one of the signal contact beams.

### CROSS-REFERENCE TO RELATED APPLICATION

This application claims the benefit of Japanese Patent Application No. 2024-005540 filed on Jan. 17, 2024, the whole disclosure of which is incorporated herein by reference.

### FIELD OF THE DISCLOSURE

The disclosure relates to an electrical interposer.

### BACKGROUND OF THE INVENTION

In the prior art, an interposer may be provided between two electronic components to electrically connect the electronic components to each other. This interposer includes a housing having a plurality of through holes and a plurality of contacts respectively inserted into and retained in the through holes. The contacts included in the interposer each comprise a base portion positioned in the through hole of the housing and retained in the housing and two contact beams respectively extending to two main faces of the housing from the base portion. The plurality of contacts can include a signal contact pair including the two signal contacts positioned to be adjacent to each other in their width direction and handling signal transmission.

Interposers according to the prior art, however, do not achieve desired electrical characteristics and/or electrical performance.

### SUMMARY OF THE INVENTION

According to an embodiment of the present disclosure, an interposer comprises a housing and a signal contact pair. The housing has a first face and a second face, and a plurality of through holes extending therebetween. Each signal contact has a base portion press-fitted into a respective one of the through holes, a first signal contact beam extending outward from the first face from the base portion and having a first contact portion, and a second signal contact beam extending outward from the second face from the base portion and having a second contact portion. The signal contact has an opening defined by the base portion and the first signal contact beam and an opening defined by the base portion and the second signal contact beam. At least one of the two signal contacts includes protruding portions protruding toward a side of the opening, respectively, 10753305.1 from the base portion and at least one of the signal contact beams.

### DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1A is an isometric view schematically illustrating an interposer according to the disclosure.

FIG. 1B is an isometric view schematically illustrating the interposer according to the disclosure that can be electrically connected to two electronic components.

FIG. 2 is a partially enlarged isometric view schematically illustrating the interposer according to the disclosure in a part surrounded by a dotted line in FIG. 1A.

FIG. 3 is a partially enlarged sectional view schematically illustrating the interposer according to the disclosure in the part surrounded by the dotted line viewed along a line A-A in FIG. 2.

FIG. 4 is an isometric view schematically illustrating an example of a contact including signal contacts having a characteristic configuration in the interposer according to the disclosure.

FIG. 5 is an isometric view schematically illustrating another example of a contact including signal contacts having a characteristic configuration in the interposer according to the disclosure.

FIG. 6 is a front view schematically illustrating another example of a contact including signal contacts having a characteristic configuration in the interposer according to the disclosure.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

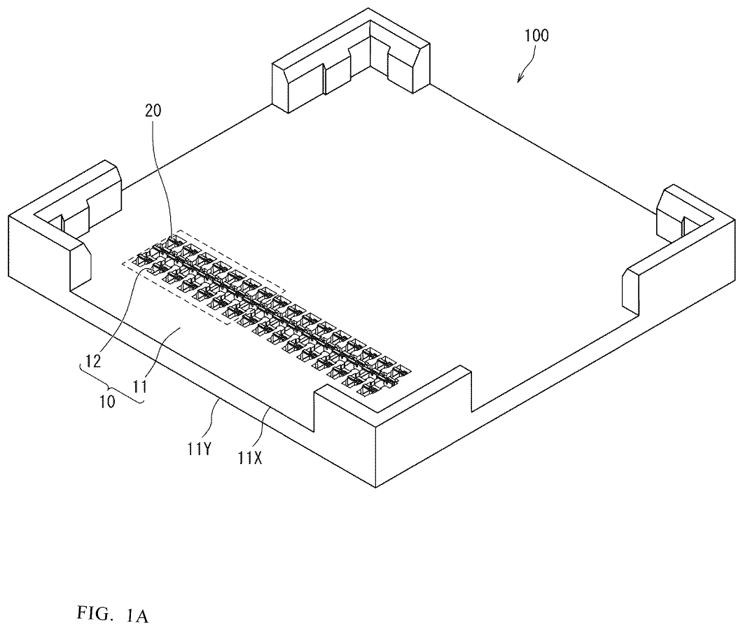

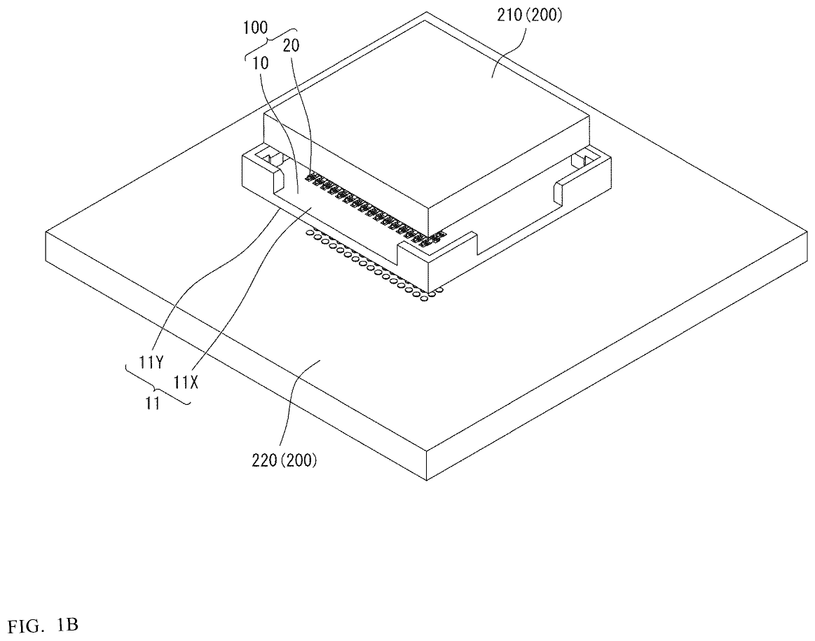

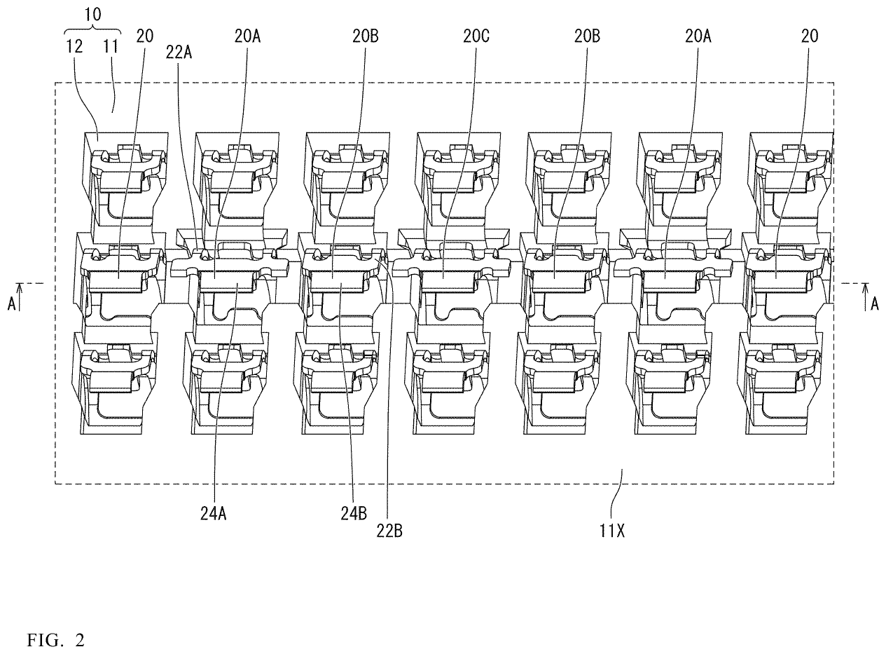

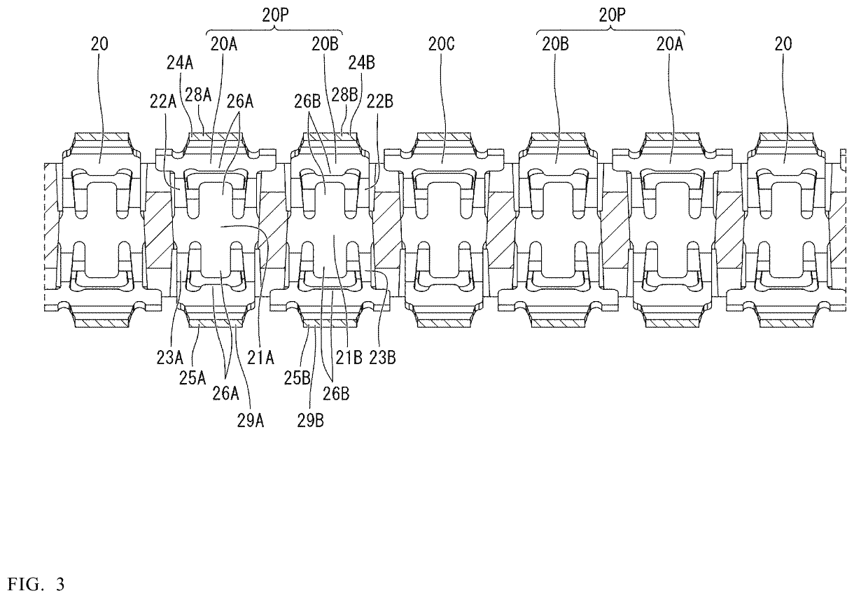

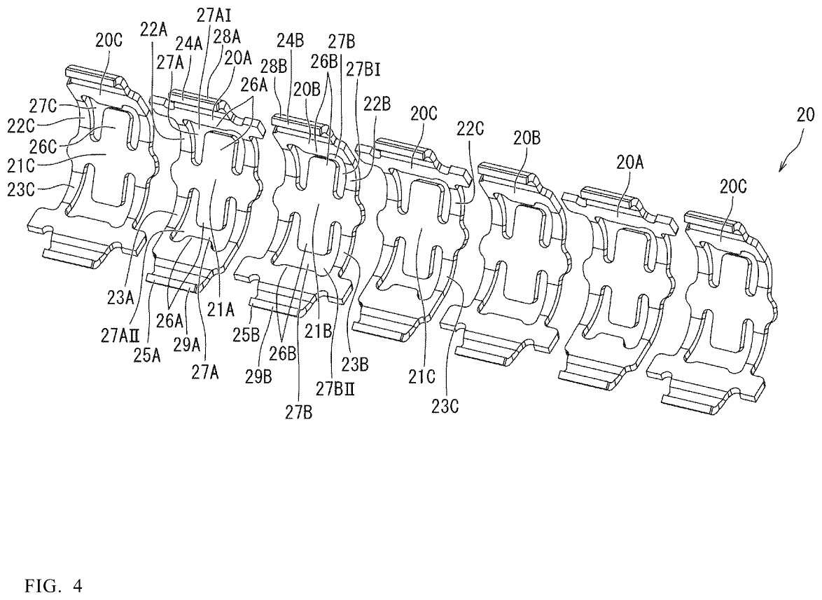

FIG. 1A is an isometric view schematically illustrating an interposer according to the disclosure. FIG. 2 is a partially enlarged isometric view schematically illustrating the interposer according to the disclosure in a part surrounded by a dotted line in FIG. 1A. FIG. 3 is a partially enlarged sectional view schematically illustrating the interposer according to the disclosure in the part surrounded by the dotted line viewed along a line A-A in FIG. 2. FIG. 4 is an isometric view schematically illustrating an example of a contact including signal contacts having a characteristic configuration in the interposer according to the disclosure.

As illustrated in FIG. 1A, an interposer 100 according to the disclosure generally includes a housing 10 and a plurality of contacts 20. The housing 10 includes a housing body portion 11 having two main faces (a first face 11X and a second face 11Y) corresponding to each other and a plurality of through holes 12 that penetrate therethrough between the two main faces (the first face 11X and the second face 11Y). The above-described first face 11X can be a face directed toward the side of a first electronic component 210 out of two electronic components 200. The second face 11Y can be a face directed toward the side of a second electronic component 220 out of the two electronic components 200 (See FIG. 1B). Although not particularly limited, examples of the above-described first electronic component 210 can include an IC (integrated circuit). Examples of the above-described second electronic component 220 can include a circuit board. In this case, the interposer 100 according to the disclosure functions to mediate signal transmission between the circuit board and the IC.

An aspect in which the plurality of through holes 12 are provided in a lattice shape in a local part of the housing body portion 11 is illustrated as an example in FIG. 1A, but without having to be limited to this, the plurality of through holes 12 may be provided in a lattice shape for a large part of the housing body portion 11. A material forming the housing 10 may be a material having an insulation property. For example, a thermoplastic resin material can be selected.

As illustrated in FIGS. 2 to 4, the plurality of contacts 20 include signal contacts for transmitting a signal (or also referred to as signal contacts) and ground contacts 20C for grounding (or also referred to as ground contacts). A material forming the contact 20 may be a metal material having an electric conductivity, for example, copper. The above-described signal contacts include a first signal contact 20A and a second signal contact 20B that can be the same in shape while being opposite in positioning direction. The first signal contact 20A and the second signal contact 20B are adjoined (i.e., paired) with a predetermined spacing in a width direction of the signal contacts to compose a signal contact pair 20P.

The ground contacts 20C can be positioned between the signal contact pairs 20P adjacent to each other and outside the signal contact pairs 20P in consideration of electrical characteristics of the interposer 100 according to the disclosure. That is, the ground contacts 20C can be positioned on both sides of each of the signal contact pairs 20P. The ground contact 20C may have the same shape as that of the first signal contact 20A and the second signal contact 20B or may have a different shape from that of the first signal contact 20A and the second signal contact 20B, as illustrated in FIGS. 2 to 4.

When the contacts are described in the description and drawings, “A” is suffixed to components of the first signal contact, “B” is suffixed to components of the second signal contact, and “C” is suffixed to components of the ground contact.

The first signal contact 20A and the second signal contact 20B can be respectively positioned in the through holes 12 adjacent to each other in the contact width direction among the plurality of through holes 12 in the above-described housing 10. The ground contacts 20C can be respectively positioned in the through holes 12 located on both sides of the signal contact pair 20P among the plurality of through holes 12 in the housing 10. Each of the plurality of contacts 20 including the signal contacts and the ground contacts 20C has a base portion that can be press-fitted into the above-described through hole 12. Such press-fitting allows the signal contact to be retained in the through hole 12 by cutting into an inner wall face of the through hole 12 when the signal contact is press-fitted into the through hole 12. In addition, each of the plurality of contacts 20 can include a first contact beam extending more outward than the first face 11X of the housing 10 from the base portion and having a first contact portion in its distal end portion. Further, each of the plurality of contacts 20 can include a second contact beam extending more outward than the second face of the housing 10 from the above-described base portion and having a second contact portion in its distal end portion.

If the above-described first electronic component 210 is an IC, a connection pad formed at a location corresponding to each of the signal contacts and for transmitting a signal is provided on a face, directed toward the first face 11X side of the housing 10, of the IC. When the IC is mounted, the first contact portion in each of the signal contacts can electrically contact the connection pad.

If the above-described second electronic component 220 is a circuit board, a connection pad formed at a location corresponding to each of the signal contacts and for transmitting a signal is provided on a face, directed toward the second face 11Y side of the housing 10, of the circuit board. When the interposer 100 according to the disclosure is mounted on the circuit board, the second contact portion in each of the signal contacts electrically contacts the connection pad on the circuit board.

As for the first signal contact 20A, the first signal contact 20A includes a base portion 21A, a first signal contact beam 22A, and a second signal contact beam 23A, as illustrated in FIGS. 2 to 4. The first signal contact 20A has two openings 27A (a first opening 27AI and a second opening 27AII) respectively including the base portion 21A and the signal contact beams 22A and 23A. This opening 27A is a spatial region surrounded by the base portion 21A and each of the signal contact beams continuous therewith. The first signal contact beam 22A extends more outward than the first face 11X of the housing 10 (also see FIG. 1A) from the base portion 21A and has a first contact portion 24A, described above, in a distal end portion 28A. The second signal contact beam 23A extends more outward than the second face (corresponding to 11Y in FIG. 1A) of the housing 10 from the above-described base portion 21A and has a second contact portion 25A, described above, in a distal end portion 29A.

Similarly, as for the second signal contact 20B, the second signal contact 20B includes a base portion 21B, a first signal contact beam 22B, and a second signal contact beam 23B, as illustrated in FIGS. 2 to 4. The second signal contact 20B has two openings 27B (a first opening 27BI and a second opening 27BII) respectively including the base portion 21B and the signal contact beams 22B and 23B. This opening 27B is a spatial region surrounded by the base portion 21B and each of the signal contact beams continuous therewith. The first signal contact beam 22B extends more outward than the first face 11X of the housing 10 (also see FIG. 1A) from the base portion 21B and has a first contact portion 24B, described above, in a distal end portion 28B. The second signal contact beam 23B extends more outward than the second face (corresponding to 11Y in FIG. 1A) of the housing 10 from the above-described base portion 21B and has a second contact portion 25B, described above, in a distal end portion 29B.

In each of the signal contacts 20A and 20B, the openings are present, whereby the signal contact, in particular the signal contact beams, can have an elastic function. When the signal contact has such an elastic function, a contact region of the above-described signal contact with the electronic component 200 can be made larger than that when it does not have an elastic function. Specifically, a contact region between the contact portion of the above-described signal contact beam and the above-described connection pad can be made large. Thus, a favorable contact between the electronic component 200 and the signal contact is ensured, thereby allowing an electrical connection therebetween to be favorably ensured.

The interposer 100 according to the disclosure is characterized by a configuration of the contact 20 as its constituent element, in particular the signal contact. Specifically, in the disclosure, at least one of the above-described two signal contacts (the first signal contact 20A/second signal contact 20B) includes protruding portions locally protruding, respectively, from the base portion and at least one of the signal contact beams toward the side of the opening (corresponding to the spatial region surrounded by the base portion and the signal contact beam).

In the disclosure, the presence of the above-described protruding portions makes it possible to make a region of the signal contact larger than when there is no such protruding portion. Such enlargement of the region of the signal contact makes it easier to adjust the electrical characteristics of the interposer 100 according to the disclosure than when there is no protruding portion and as a result to make it possible to further improve the electrical characteristic of the interposer 100.

In addition, the enlargement of the region of the signal contact due to the above-described protruding portions makes it possible to more suppress an inclination of the contact during insertion of the contact into the through hole 12 of the housing body portion and during the press-fitting thereof into the through hole 12 than when there is no protruding portion. That is, the protruding portions can favorably function as a location stabilization member (stabilizer) for the contact.

In an example, the first signal contact 20A can include protruding portions 26A locally protruding toward the first opening 27AI side, respectively, from the base portion 21A and the first signal contact beam 22A, as illustrated in FIGS. 3 and 4. That is, the plurality of protruding portions 26A are located in the first opening 27AI. In an illustrated aspect, the two protruding portions 26A are present in a formation region of the first opening 27AI.

In addition, the first signal contact 20A can include protruding portions 26A locally protruding toward the second opening 27AII side, respectively, from the base portion 21A and the second signal contact beam 23A. That is, the plurality of protruding portions 26A are located in the second opening 27AII. In the illustrated aspect, the two protruding portions 26A are present in a formation region of the second opening 27AII.

From the foregoing, the first signal contact 20A can include the plurality of protruding portions 26A in the aspect illustrated in FIGS. 3 and 4. The presence of the plurality of protruding portions 26A in the first signal contact 20A makes it easier to adjust the electrical characteristics of the above-described interposer 100. This can result in a further improvement in the electrical characteristics of the interposer 100.

Further, the second signal contact 20B can include protruding portions 26B locally protruding toward the first opening 27BI side, respectively, from the base portion 21B and the first signal contact beam 22B, as illustrated in FIGS. 3 and 4. That is, the plurality of protruding portions 26B are located in the first opening 27BI. In the illustrated aspect, the two protruding portions 26B are present in a formation region of the first opening 27BI.

In addition, the second signal contact 20B can include protruding portions 26B locally protruding toward the second opening 27BII side, respectively, from the base portion 21B and the second signal contact beam 23B. That is, the plurality of protruding portions 26B are located in the second opening 27BII. In the illustrated aspect, the two protruding portions 26B are present in a formation region of the second opening 27BII.

From the foregoing, the second signal contact 20B can include the plurality of protruding portions 26B in the aspect illustrated in FIGS. 3 and 4. The presence of the plurality of protruding portions 26B makes it easier to adjust the electrical characteristics of the above-described interposer 100. This can result in a further improvement in the electrical characteristics of the interposer 100.

In the first signal contact 20A and/or the second signal contact 20B, the plurality of protruding portions located in the one opening preferably separate from one another from the viewpoint of favorably ensuring an elastic function of the signal contact beam. In one example, both the two protruding portions 26A may separate from and oppose each other when located in the one opening 27A, as illustrated in FIGS. 3 and 4. Similarly, both the two protruding portions 26B may separate from and oppose each other when located in the one opening 27B. In this case, the one opening itself may have an H shape.

Particularly, as in the above-described one example, when both the first signal contact 20A and the second signal contact 20B each have the plurality of protruding portions, a larger number of protruding portions in a signal contact pair can be ensured as a whole. In the aspect illustrated in FIGS. 3 and 4, a total of eight protruding portions can be ensured in the signal contact pair. This makes it easier to adjust the electrical characteristics of the above-described interposer 100. This can result in a further improvement in the electrical characteristics of the interposer 100.

If the number of the above-described protruding portions provided is one or more, the protruding portion may protrude toward the above-mentioned opening side from at least one of the first signal contact beam and the second signal contact beam in the first signal contact 20A and/or the second signal contact 20B, for example, without having to be limited to that in the one example illustrated in FIGS. 3 and 4.

The protruding portion may protrude toward the above-described opening side from at least one side of the base portion in the first signal contact 20A and/or the second signal contact 20 B. From the viewpoint of ensuring the above-described plurality of protruding portions, the protruding portions preferably protrude toward the opening side, respectively, from both sides of each of the base portions 21A and 21B.

Further, although the protruding portion can favorably function as a location stabilization member (stabilizer) for the contact, as described above, the following configuration is preferably adopted from the viewpoint of increasing a contact area of the above-described protruding portion in the contact with the inner wall face of the through hole 12 of the housing 10 to make contact thereof with the wall face easier.

Specifically, respective sizes of main faces of the protruding portion protruding from the base portion and the protruding portion protruding from the signal contact beam may be made different from each other. In this case, the protruding portion the main face of which has the larger size can be positioned to contact the inner wall face of the through hole 12 of the housing 10. Specifically, the size of the main face of the protruding portion protruding from the base portion can be made larger than the size of the main face of the protruding portion protruding from the signal contact beam.

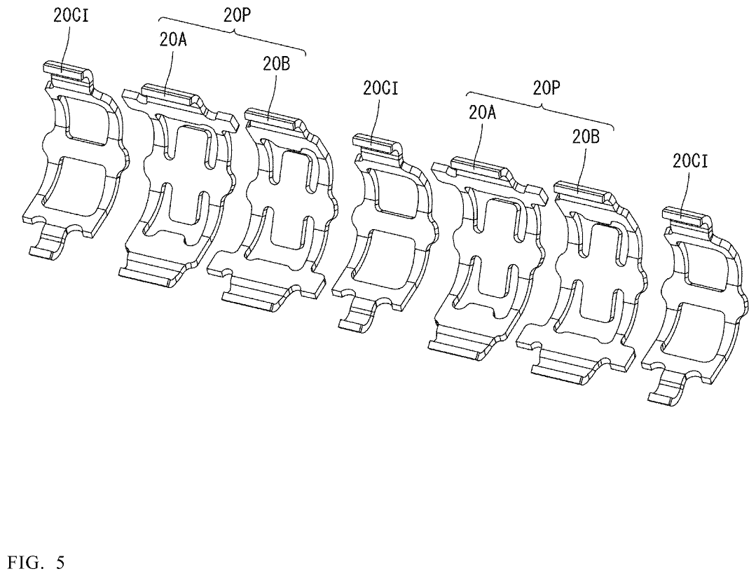

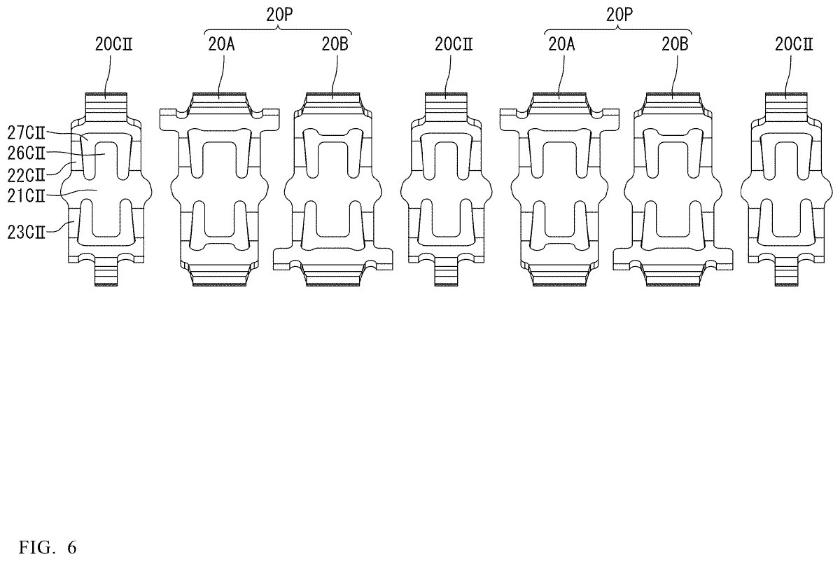

The ground contact 20C can have the same shape as that of the first signal contact 20A and the second signal contact 20B, as illustrated in FIGS. 2 to 4, in an example. In another example, a ground contact 20CI may have a different shape from that of the first signal contact 20A and the second signal contact 20B, as illustrated in FIG. 5. In still another example, a ground contact 20CII can include similar protruding portions to those in the above-described signal contact in consideration of an improvement in the electrical characteristics of the interposer 100 according to the disclosure, as illustrated in FIG. 6. The ground contact 20C illustrated in FIG. 4 can also include similar protruding portions to those in the signal contact.

In FIG. 4, the ground contact 20C can include a base portion 21C press-fitted into the through hole 12 of the housing 10, a first ground contact beam 22C extending more outward than the first face 11X of the housing body portion 11 from the base portion 21C, and a second ground contact beam 23C extending more outward than the second face 11Y of the housing body portion 11 from the base portion 21C. Under such a configuration, the ground contact 20C can include protruding portions 26C locally protruding toward the side of an opening 27C of the ground contact 20C, respectively, from the base portion 21C and at least one of the ground contact beams.

The interposer 100 according to the disclosure is not limited to that in the above-described embodiment. Changes may be made, as needed, within the scope of the disclosure.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. An interposer comprising:
a housing including a housing body portion having a first face arranged to oppose a side of a first electronic component and a second face arranged to oppose a side of a second electronic component, and a plurality of through holes extending between the first face and the second face; and
a signal contact pair including two signal contacts, each of which includes a base portion press-fitted into a respective one of the plurality of through holes, a first signal contact beam extending further outward than the first face from the base portion and having a first contact portion for contacting the first electrical component, and a second signal contact beam extending further outward than the second face from the base portion and having a second contact portion for contacting the second electrical component, the signal contacts adjacent to each other with a predetermined spacing in a width direction of the signal contacts, wherein:
the signal contact has an opening defined by the base portion and the first signal contact beam and an opening defined by the base portion and the second signal contact beam; and
at least one of the two signal contacts includes protruding portions locally protruding toward a side of the opening, respectively, from the base portion and at least one of the signal contact beams.

2. The interposer according to claim 1, wherein the signal contact includes a plurality of protruding portions.

3. The interposer according to claim 1, wherein the protruding portion protrudes toward the opening side from at least one of the first signal contact beam and the second signal contact beam.

4. The interposer according to claim 1, wherein the protruding portion protrudes toward the opening side from at least one side of the base portion.

5. The interposer according to claim 1, wherein the plurality of protruding portions are located in the one opening.

6. The interposer according to claim 5, wherein the plurality of protruding portions located in the one opening separate from one another.

7. The interposer according to claim 5, wherein in the one opening, respective sizes of main faces of the protruding portion protruding from the base portion and the protruding portion protruding from the signal contact beam differ from each other.

8. The interposer according to claim 7, wherein the size of the main face of the protruding portion protruding from the base portion is larger than the size of the main face of the protruding portion protruding from the signal contact beam.

9. The interposer according to claim 6, wherein the one opening has an H shape.

10. The interposer according to claim 1, further comprising ground contacts respectively positioned on each side of the signal contact pair.

11. The interposer according to claim 10, wherein the ground contact includes a base portion press-fitted into one of the plurality of the through holes, a first ground contact beam extending more outward than the first face from the base portion, and a second ground contact beam extending more outward than the second face from the base portion, and includes protruding portions locally protruding toward the opening side, respectively, from the base portion and at least one of the ground contact beams.

12. An electrical assembly, comprising:
a first electrical component;
a second electrical component; and
an interposer, including:
a housing having a housing body portion having a first face arranged to oppose a side of a first electronic component and a second face arranged to oppose a side of a second electronic component, and a plurality of through holes extending between the first face and the second face; and
a signal contact pair including two signal contacts, each of which includes a base portion press-fitted into a respective one of the plurality of through holes, a first signal contact beam extending further outward than the first face from the base portion and having a first contact portion for contacting the first electrical component, and a second signal contact beam extending further outward than the second face from the base portion and having a second contact portion for contacting the second electrical component, the signal contacts adjacent to each other with a predetermined spacing in a width direction of the signal contacts, the signal contact has an opening defined by the base portion and the first signal contact beam and an opening defined by the base portion and the second signal contact beam, and at least one of the two signal contacts includes protruding portions locally protruding toward a side of the opening, respectively, from the base portion and at least one of the signal contact beams.

13. The assembly according to claim 12, wherein the signal contact includes a plurality of protruding portions.

14. The assembly according to claim 12, wherein the protruding portion protrudes toward the opening side from at least one of the first signal contact beam and the second signal contact beam.

15. The assembly according to claim 12, wherein the protruding portion protrudes toward the opening side from at least one side of the base portion.

16. The assembly according to claim 12, wherein the plurality of protruding portions are located in the one opening.

17. The assembly according to claim 16, wherein the plurality of protruding portions located in the one opening are arranged on opposing sides of the opening.

18. The assembly according to claim 16, wherein:
in the one opening, respective sizes of main faces of the protruding portion protruding from the base portion and the protruding portion protruding from the signal contact beam differ from each other; and
the size of the main face of the protruding portion protruding from the base portion is larger than the size of the main face of the protruding portion protruding from the signal contact beam.

19. The assembly according to claim 1, further comprising ground contacts respectively positioned on each side of the signal contact pair.

20. The assembly according to claim 19, wherein the ground contact includes a base portion press-fitted into one of the plurality of the through holes, a first ground contact beam extending further outward than the first face from the base portion, and a second ground contact beam extending further outward than the second face from the base portion, and includes protruding portions locally protruding toward the opening side, respectively, from the base portion and at least one of the ground contact beams.
